(19) United States
(12) Patent Application Publication
(10) Pub. No.: US 2025/0207258 A1
(43) Pub. Date: Jun. 26, 2025

(54) Substrate Processing Apparatus, Substrate Support, Substrate Processing Method, Method of Manufacturing Semiconductor Device and Non-transitory Computer-readable Recording Medium

(71) Applicant: Kokusai Electric Corporation, Tokyo (JP)

(72) Inventor: Arito OGAWA, Toyama (JP)

(21) Appl. No.: 19/048,416

(22) Filed: Feb. 7, 2025

Related U.S. Application Data
(63) Continuation of application No. PCT/JP2023/011299, filed on Mar. 22, 2023.

(30) Foreign Application Priority Data
Aug. 9, 2022 (JP) 2022-126764

(51) Int. Cl. C23C 16/458; C23C 16/44; C23C 16/455

(52) U.S. Cl. CPC C23C 16/4585; C23C 16/4412; C23C 16/45574

(57) ABSTRACT

It is possible to improve a uniformity of a substrate processing between substrates. There is provided a technique that includes: a substrate support provided with a processing region in which a plurality of substrates are placed, and comprising a plurality of mounting structures on which the plurality of substrates are placed, respectively, such that a substrate spacing between adjacent substrates in an upper region of the processing region and a substrate spacing between adjacent substrates in a lower region of the processing region are set to be narrower than a substrate spacing between adjacent substrates in a central region of the processing region; a process vessel configured to accommodate the substrate support; a gas supplier configured to supply a process gas into the process vessel; and an exhauster configured to exhaust an inner atmosphere of the process vessel.

### CROSS REFERENCE TO RELATED APPLICATIONS

This application is a bypass continuation application of PCT International Application No. PCT/JP2023/011299, filed on Mar. 22, 2023, in the WIPO, the international application being based upon and claiming the benefit of priority from Japanese Patent Application No. 2022-126764, filed on Aug. 9, 2022, in the Japanese Patent Office, the entire contents of which are hereby incorporated by reference.

### TECHNICAL FIELD

The present disclosure relates to a substrate processing apparatus, a substrate support, a substrate processing method, a method of manufacturing a semiconductor device and a non-transitory computer-readable recording medium.

### BACKGROUND

For example, a metal film whose resistance is low is used as a word line of a DRAM or a NAND flash memory of a three-dimensional structure. Further, according to some related arts, a barrier film may be formed between the metal film and an insulating film.

However, when forming a film on a substrate, an amount of reaction by-products generated may vary depending on a location (arrangement location) of the substrate. Thereby, a thickness of the film formed on the substrate may vary.

### SUMMARY

According to the present disclosure, there is provided a technique capable of improving a uniformity of a substrate processing between substrates.

According to an embodiment of the present disclosure, there is provided a technique that includes: a substrate support provided with a processing region in which a plurality of substrates are placed, and including a plurality of mounting structures on which the plurality of substrates are placed, respectively, such that a substrate spacing between adjacent substrates in an upper region of the processing region and a substrate spacing between adjacent substrates in a lower region of the processing region are set to be narrower than a substrate spacing between adjacent substrates in a central region of the processing region; a process vessel configured to accommodate the substrate support; a gas supplier configured to supply a process gas into the process vessel; and an exhauster configured to exhaust an inner atmosphere of the process vessel.

### BRIEF DESCRIPTION OF THE DRAWINGS

FIG. 1 is a diagram schematically illustrating a vertical cross-section of a vertical type process furnace of a substrate processing apparatus according to one or more embodiments of the technique of the present disclosure.

FIG. 2 is a diagram schematically illustrating a horizontal cross-section taken along a line A-A of the substrate processing apparatus shown in FIG. 1.

FIG. 3 is a diagram schematically illustrating arrangement positions of holes of a nozzle and an arrangement position of a substrate support with respect to a processing region for substrates according to the embodiments of the present disclosure.

FIG. 4 is a diagram schematically illustrating a relationship between a substrate support according to a comparative example of the present disclosure and a thickness of a film formed on a substrate.

FIG. 5 is a diagram schematically illustrating an example of the substrate support according to the embodiments of the present disclosure.

FIG. 6 is a diagram schematically illustrating a relationship between the substrate support according to the embodiments of the present disclosure and the thickness of the film formed on the substrate.

FIG. 7 is a diagram schematically illustrating a relationship between a substrate spacing pattern of the substrate support according to the embodiments of the present disclosure and the thickness of the film formed on the substrate.

FIG. 8 is a block diagram schematically illustrating a configuration of a controller and related components of the substrate processing apparatus according to the embodiments of the present disclosure.

FIG. 9 is a diagram schematically illustrating a substrate processing sequence according to the embodiments of the present disclosure.

FIG. 10 is a diagram schematically illustrating a modified example of the substrate processing sequence according to the embodiments of the present disclosure.

FIG. 11 is a diagram schematically illustrating a modified example of a third nozzle of the substrate processing apparatus according to the embodiments of the present disclosure, wherein arrangement positions of holes of the third nozzle and the arrangement position of the substrate support with respect to the processing region for the substrates are shown.

### DETAILED DESCRIPTION

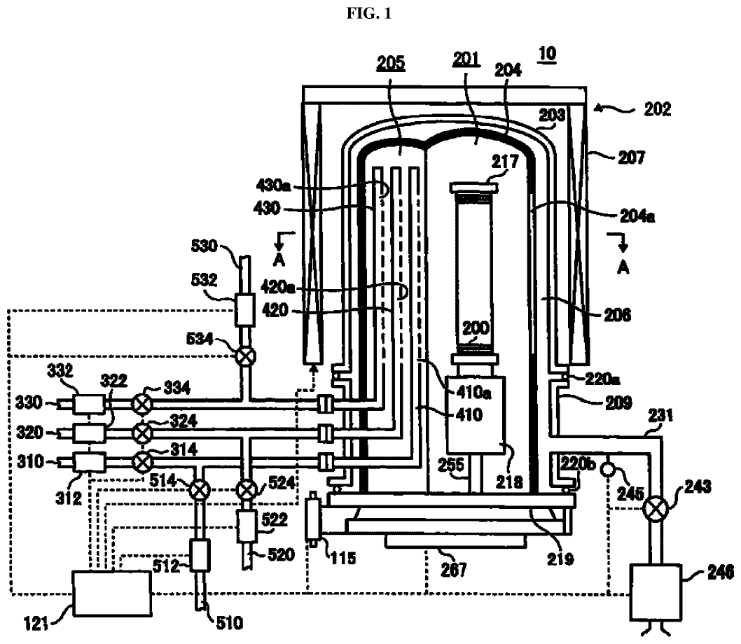

Hereinafter, one or more embodiments (also simply referred to as “embodiments”) according to the technique of the present disclosure will be described mainly with reference to FIGS. 1 to 9. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

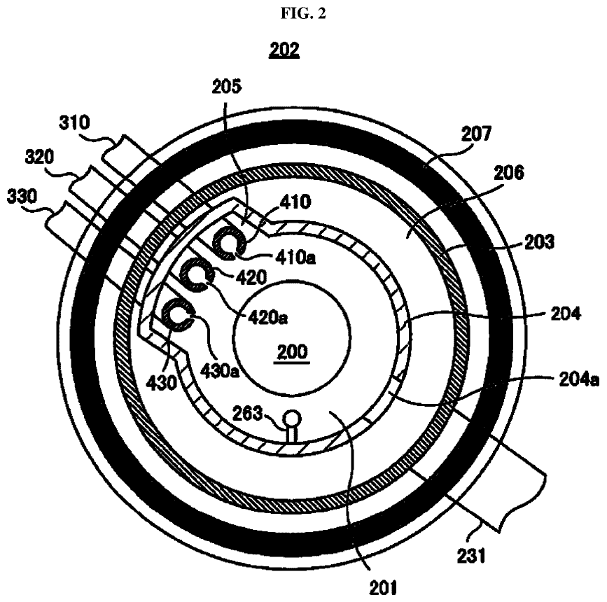

FIG. 1 is a diagram schematically illustrating a vertical cross-section of a process furnace 202 provided in a substrate processing apparatus capable of performing a method of manufacturing a semiconductor device (hereinafter, simply referred to as a “substrate processing apparatus 10”), and FIG. 2 is a diagram schematically illustrating a horizontal cross-section, taken along a line A-A shown in FIG. 1, of the process furnace 202 of the substrate processing apparatus 10. Hereinafter, the present embodiments will be described by way of an example in which a metal-containing film is formed on a wafer 200 serving as a substrate in the process furnace 202.

The process furnace 202 is provided with a heater 207 serving as a heater (which is a heating structure, a heating apparatus or a heating system). The heater 207 is of a cylindrical shape, and is vertically installed while being supported by a heater base (not shown) serving as a support plate.

An outer tube 203 constituting a reaction vessel (also referred to as a “process vessel”) is provided in an inner side of the heater 207 to be aligned in a manner concentric with the heater 207. The outer tube 203 may also be referred to as an “outer reaction tube” or an “outer vessel”. For example, the outer tube 203 is made of a heat resistant material such as quartz (SiO₂) and silicon carbide (SiC). For example, the outer tube 203 is of a cylindrical shape with a closed upper end and an open lower end. A manifold (also referred to as an “inlet flange”) 209 is provided under the outer tube 203 to be aligned in a manner concentric with the outer tube 203. For example, the manifold 209 is made of a metal such as stainless steel (SUS). For example, the manifold 209 is of a cylindrical shape with open upper and lower ends. An O-ring 220a serving as a seal is provided between the upper end of the manifold 209 and the outer tube 203. As the manifold 209 is supported by the heater base (not shown), the outer tube 203 is installed vertically.

An inner tube 204 constituting the reaction vessel is provided in an inner side of the outer tube 203. The inner tube 204 may also be referred to as an “inner reaction tube” or an “inner vessel”. For example, the inner tube 204 is made of a heat resistant material such as quartz (SiO₂) and silicon carbide (SiC). For example, the inner tube 204 is of a cylindrical shape with a closed upper end and an open lower end. The process vessel is constituted mainly by the outer tube 203, the inner tube 204 and the manifold 209. A process chamber 201 is provided in a hollow cylindrical portion of the process vessel (that is, an inside (inner portion) of the inner tube 204). The present embodiments will be described by way of an example in which the process vessel includes the inner tube 204 (that is, the process chamber 201 is provided in the inner side of the inner tube 204). However, the present embodiments may also be applied when the process vessel does not include the inner tube 204.

The process chamber 201 is configured to be capable of accommodating a plurality of wafers including the wafer 200 serving as the substrate in a horizontal orientation to be vertically arranged in a multistage manner by a boat 217 (which serves as a substrate support) described later. Hereinafter, the plurality of wafers including the wafer 200 may also be simply referred to as “wafers 200”.

A nozzle 410 serving as a first nozzle, a nozzle 420 serving as a second nozzle and a nozzle 430 serving as a third nozzle are installed in the process chamber 201 so as to penetrate a side wall of the manifold 209 and the inner tube 204. Gas supply pipes 310, 320 and 330 serving as gas supply lines are connected to the nozzles 410, 420 and 430, respectively. In a manner described above, for example, the three nozzles 410, 420 and 430 and the three gas supply pipes 310, 320 and 330 are provided at the substrate processing apparatus 10, and thereby it is possible to supply various gases into the process chamber 201 through the three nozzles 410, 420 and 430 and the three gas supply pipes 310, 320 and 330. However, the process furnace 202 of the present embodiments is not limited to the example described above.

Mass flow controllers (MFCs) 312, 322 and 332 serving as flow rate controllers (flow rate control structures) and valves 314, 324 and 334 serving as opening/closing valves are sequentially installed at the gas supply pipes 310, 320 and 330 in this order from upstream sides to downstream sides of the gas supply pipes 310, 320 and 330 in a gas flow direction, respectively. Further, gas supply pipes 510, 520 and 530 through which an inert gas is supplied are connected to the gas supply pipes 310, 320 and 330 at downstream sides of the valves 314, 324 and 334, respectively. MFCs 512, 522 and 532 and valves 514, 524 and 534 are sequentially installed at the gas supply pipes 510, 520 and 530 in this order from upstream sides to downstream sides of the gas supply pipes 510, 520 and 530 in the gas flow direction, respectively.

The nozzles 410, 420 and 430 are connected to front ends (tips) of the gas supply pipes 310, 320 and 330, respectively. Each of the nozzles 410, 420 and 430 is configured as an L-shaped nozzle. Horizontal portions of the nozzles 410, 420 and 430 are installed so as to penetrate the side wall of the manifold 209 and the inner tube 204. Vertical portions of the nozzles 410, 420 and 430 are installed in a preliminary chamber 205 of a channel shape (a groove shape) protruding outward in a radial direction of the inner tube 204 and extending in a vertical direction. That is, the vertical portions of the nozzles 410, 420 and 430 are installed in the preliminary chamber 205 to extend toward the upper end of the inner tube 204 (that is, upward in an arrangement direction of the wafers 200) and along an inner wall of the inner tube 204.

The nozzles 410, 420 and 430 extend from a lower region of the process chamber 201 to an upper region of the process chamber 201. The nozzles 410, 420 and 430 are provided with a plurality of gas supply holes 410a, a plurality of gas supply holes 420a and a plurality of gas supply holes 430a, respectively, at positions facing the wafers 200. Thereby, process gases can be supplied to the wafers 200 through the gas supply holes 410a of the nozzle 410, the gas supply holes 420a of the nozzle 420 and the gas supply holes 430a of the nozzle 430, respectively. The gas supply holes 410a, the gas supply holes 420a and the gas supply holes 430a are provided from a lower portion to an upper portion of the inner tube 204. An opening area of each of the gas supply holes 410a, the gas supply holes 420a and the gas supply holes 430a is the same, and each of the gas supply holes 410a, the gas supply holes 420a and the gas supply holes 430a is provided at the same opening pitch. However, the gas supply holes 410a, the gas supply holes 420a and the gas supply holes 430a are not limited thereto. For example, the opening area of each of the gas supply holes 410a, the gas supply holes 420a and the gas supply holes 430a may gradually increase from the lower portion to the upper portion of the inner tube 204 to further uniformize a flow rate of each of the process gases respectively supplied through the gas supply holes 410a, the gas supply holes 420a and the gas supply holes 430a.

The gas supply holes 410a of the nozzle 410, the gas supply holes 420a of the nozzle 420 and the gas supply holes 430a of the nozzle 430 are located within a region extending from a lower portion to an upper portion of the boat 217 described later. Therefore, the process gases (which are respectively supplied into the process chamber 201 through the gas supply holes 410a, the gas supply holes 420a and the gas supply holes 430a) are supplied onto the wafers 200 accommodated in the boat 217 from the lower portion to the upper portion thereof, that is, an entirety of the wafers 200 accommodated in the boat 217. It is preferable that the nozzles 410, 420 and 430 extend from the lower region to the upper region of the process chamber 201. However, the nozzles 410, 420 and 430 may extend only to the vicinity of a ceiling of the boat 217.

A first process gas serving as one of the process gases is supplied into the process chamber 201 through the gas supply pipe 310 provided with the MFC 312 and the valve 314 and the nozzle 410.

A second process gas serving as one of the process gases is supplied into the process chamber 201 through the gas supply pipe 320 provided with the MFC 322 and the valve 324 and the nozzle 420.

A third process gas serving as one of the process gases is supplied into the process chamber 201 through the gas supply pipe 330 provided with the MFC 332 and the valve 334 and the nozzle 430. Hereinafter, each of the process gases may also be referred to as a “process gas.”

The inert gas is supplied into the process chamber 201 through the gas supply pipes 510, 520 and 530 provided with the MFCs 512, 522 and 532 and the valves 514, 524 and 534, respectively, and the nozzles 410, 420 and 430.

A process gas supplier (which is a process gas supply structure or a process gas supply system) is constituted mainly by the gas supply pipes 310, 320 and 330, the MFCs 312, 322 and 332, the valves 314, 324 and 334 and the nozzles 410, 420 and 430. However, the nozzles 410, 420 and 430 alone may be referred to as the “process gas supplier”. The process gas supplier may also be simply referred to as a “gas supplier” which is a gas supply structure or a gas supply system. When the first process gas is supplied through the gas supply pipe 310, a first process gas supplier (which is a first process gas supply structure or a first process gas supply system) is constituted mainly by the gas supply pipe 310, the MFC 312 and the valve 314. However, the first process gas supplier may further include the nozzle 410. Further, when the second process gas is supplied through the gas supply pipe 320, a second process gas supplier (which is a second process gas supply structure or a second process gas supply system) is constituted mainly by the gas supply pipe 320, the MFC 322 and the valve 324. However, the second process gas supplier may further include the nozzle 420. For example, when a nitrogen-containing gas serving as the second process gas is supplied through the gas supply pipe 320, the second process gas supplier may also be simply referred to as a “nitrogen-containing gas supplier” which is a nitrogen-containing gas supply structure or a nitrogen-containing gas supply system. Further, when the third process gas is supplied through the gas supply pipe 330, a third process gas supplier (which is a third process gas supply structure or a third process gas supply system) is constituted mainly by the gas supply pipe 330, the MFC 332 and the valve 334. However, the third process gas supplier may further include the nozzle 430. When an adsorption inhibiting gas serving as the third process gas is supplied through the gas supply pipe 330, the third process gas supplier may also be simply referred to as an “adsorption inhibiting gas supplier” which is an adsorption inhibiting gas supply structure or an adsorption inhibiting gas supply system. In addition, an inert gas supplier (which is an inert gas supply structure or an inert gas supply system) is constituted mainly by the gas supply pipes 510, 520 and 530, the MFCs 512, 522 and 532 and the valves 514, 524 and 534.

According to the present embodiments, the gas is supplied into a vertically long annular space (that is, a cylindrical space) which is defined by the inner wall of the inner tube 204 and edges (peripheries) of the wafers 200 through the nozzles 410, 420 and 430 provided in the preliminary chamber 205. Then, the gas is ejected into the inner tube 204 through the gas supply holes 410a of the nozzle 410, the gas supply holes 420a of the nozzle 420 and the gas supply holes 430a of the nozzle 430, which are provided at positions facing the wafers 200. Specifically, the gases such as the process gases are ejected into the inner tube 204 in a horizontal direction, that is, in a direction parallel to surfaces of the wafers 200 through the gas supply holes 410a of the nozzle 410, the gas supply holes 420a of the nozzle 420 and the gas supply holes 430a of the nozzle 430, respectively.

An exhaust hole (which is an exhaust port) 204a is a through-hole facing the nozzles 410, 420 and 430, and is provided at a side wall of the inner tube 204. For example, the exhaust hole 204a may be provided at a location 180° opposite to the preliminary chamber 205, and the exhaust hole 204a may be of a narrow slit-shaped through-hole elongating vertically. Therefore, the gases (which are respectively supplied into the process chamber 201 through the gas supply holes 410a of the nozzle 410, the gas supply holes 420a of the nozzle 420 and the gas supply holes 430a of the nozzle 430) flow over the surfaces of the wafers 200. The gases (residual gases) that have flowed over the surfaces of the wafers 200 are exhausted through the exhaust hole 204a into an exhaust path 206 (that is, a gap provided between the inner tube 204 and the outer tube 203). Then, the gases flowing in the exhaust path 206 are supplied into an exhaust pipe 231, and are then discharged (exhausted) out of the process furnace 202.

The exhaust hole 204a is provided to face the wafers 200 (preferably, to face the boat 217 from the upper portion to the lower portion thereof). The gases supplied in the vicinity of the wafers 200 in the process chamber 201 through the gas supply holes 410a, the gas supply holes 420a and the gas supply holes 430a are supplied (or flow) in the horizontal direction (that is, along the direction parallel to the surfaces of the wafers 200), and then are exhausted through the exhaust hole 204a into the exhaust path 206. That is, the gases (residual gases) remaining in the process chamber 201 are exhausted along the direction parallel to the surfaces (main surfaces) of the wafers 200 through the exhaust hole 204a. Further, the exhaust hole 204a is not limited to the slit-shaped through-hole. For example, the exhaust hole 204a may be configured as a plurality of holes.

The exhaust pipe 231 through which an atmosphere (inner atmosphere) of the process chamber 201 is exhausted is installed at the manifold 209. A pressure sensor 245 serving as a pressure detector (pressure detecting structure) configured to detect a pressure (inner pressure) of the process chamber 201, an APC (Automatic Pressure Controller) valve 243 and a vacuum pump 246 serving as a vacuum exhaust apparatus are sequentially installed at the exhaust pipe 231 in this order from an upstream side to a downstream side of the exhaust pipe 231 in the gas flow direction. With the vacuum pump 246 in operation, the APC valve 243 may be opened or closed to perform a vacuum exhaust of the process chamber 201 or stop the vacuum exhaust. Further, with the vacuum pump 246 in operation, an opening degree of the APC valve 243 may be adjusted in order to adjust the inner pressure of the process chamber 201. An exhauster (which is an exhaust structure or an exhaust system) (that is, an exhaust line) is constituted mainly by the exhaust hole 204a, the exhaust path 206, the exhaust pipe 231, the APC valve 243 and the pressure sensor 245. In addition, the exhauster may further include the vacuum pump 246.

A seal cap 219 serving as a furnace opening lid capable of airtightly sealing a lower end opening of the manifold 209 is provided under the manifold 209. The seal cap 219 is in contact with the lower end of the manifold 209 from thereunder. For example, the seal cap 219 is made of a metal such as SUS, and is of a disk shape. An O-ring 220b serving as a seal is provided on an upper surface of the seal cap 219 so as to be in contact with the lower end of the manifold 209. A rotator (which is a rotating structure) 267 configured to rotate the boat 217 accommodating the wafers 200 is provided at the seal cap 219 in a manner opposite to the process chamber 201. A rotating shaft 255 of the rotator 267 is connected to the boat 217 through the seal cap 219. As the rotator 267 rotates the boat 217, the wafers 200 are rotated. The seal cap 219 may be elevated or lowered in the vertical direction by a boat elevator 115 serving as an elevating structure vertically provided outside the outer tube 203. When the seal cap 219 is elevated or lowered in the vertical direction by the boat elevator 115, the boat 217 can be transferred (loaded) into the process chamber 201 or transferred (unloaded) out of the process chamber 201. The boat elevator 115 serves as a transfer device (which is a transfer structure or a transfer system) configured to load the boat 217 and the wafers 200 accommodated in the boat 217 into the process chamber 201 and to unload the boat 217 and the wafers 200 accommodated in the boat 217 out of the process chamber 201.

As shown in FIG. 2, a temperature sensor 263 serving as a temperature detector is installed in the inner tube 204. An amount of an electric current supplied (or applied) to the heater 207 is adjusted based on temperature information detected by the temperature sensor 263 such that a desired temperature distribution of a temperature (inner temperature) of the process chamber 201 can be obtained. Similar to the nozzles 410, 420 and 430, the temperature sensor 263 is L-shaped, and is provided along the inner wall of the inner tube 204.

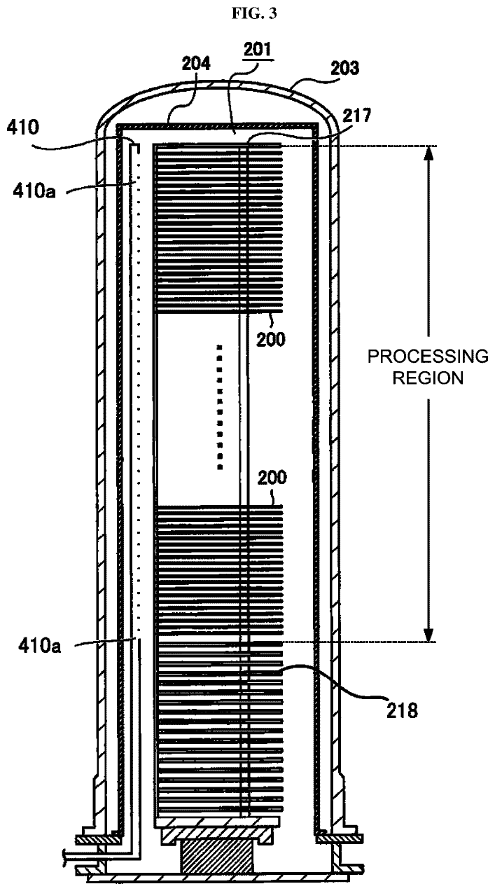

As shown in FIG. 3, the boat 217 is configured to accommodate (or support) the wafers 200 (for example, 25 wafers to 200 wafers) while the wafers 200 are horizontally oriented in a multistage manner with their centers aligned with one another with a predetermined interval (also referred to as a “substrate spacing”) therebetween in the vertical direction. The wafer 200 is placed on a mounting structure (placement structure) provided on support columns of the boat 217. That is, the wafers 200 are placed on a plurality of mounting structures 217a, respectively. For example, the boat 217 is made of a heat resistant material such as SiO₂ and SiC. A plurality of heat insulating plates 218 (which are horizontally oriented) are placed under the boat 217 in a multistage manner. Each of the heat insulating plates 218 is made of a heat resistant material such as SiO₂ and SiC. With such a configuration, the heat insulating plates 218 suppress a transmission of the heat from the heater 207 to the seal cap 219. However, the present embodiments are not limited thereto. For example, instead of the heat insulating plates 218, a heat insulating cylinder (not shown) such as a cylinder made of a heat resistant material such as SiO₂ and SiC may be provided under the boat 217.

In the present embodiments, a region of the boat 217 where the wafers 200 are placed and which faces the gas supply holes 410a of the nozzle 410 may also be referred to as a “processing region” for the wafers 200.

For example, when a film is formed on a product substrate (which is a product wafer, also simply referred to as a “wafer”) by supplying the process gas using the substrate processing apparatus 10 mentioned above, in an upper region (also referred to as an “upper end portion”) and a lower region (also referred to as a “lower end portion”) of the processing region, an amount of reaction by-products generated is set to be smaller as compared with a central region (also referred to as a “central portion”) of the processing region. Such a phenomenon occurs because the number of product substrates is set to be smaller (that is, a density is smaller) in the upper end portion and the lower end portion of the processing region as compared with the central portion of the processing region. In the present embodiments, the term “product substrate” refers to a substrate on which a fine pattern of a structure of the semiconductor device is formed. The reaction by-products may serve as an inhibitor capable of inhibiting (suppressing) a formation of the film on the product substrate. Therefore, a thickness of the film formed on the product substrates in the upper end portion and the lower end portion of the processing region (where the amount of the reaction by-products generated is set to be smaller) is set to be thicker than the thickness of the film formed on the product substrates in the central portion of the processing region. As a result, a uniformity of a substrate processing between the wafers (substrates) may deteriorate. In addition, when dummy substrates (also referred to as “dummy wafers”) are provided in an upper end portion and a lower end portion of the boat 217, because a surface area of each of the dummy wafers is set to be smaller than a surface area of each of the product substrates, the amount of the reaction by-products is set to be smaller in the upper end portion and the lower end portion of the processing region, and the thickness of the film formed on the product substrates in the upper end portion and the lower end portion of the processing region is set to be thicker than the thickness of the film formed on the product substrates in the central portion of the processing region. As a result, the uniformity of the substrate processing between the wafers (substrates) may deteriorate. Such a phenomenon is likely to occur when the surface area of each of the product substrates is large.

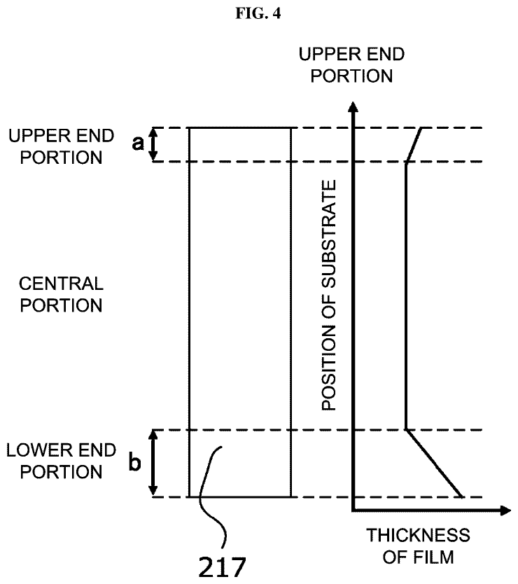

FIG. 4 is a diagram schematically illustrating a relationship (positional relationship) between the thickness of the film formed on the wafers 200 accommodated in the boat 217 and positions in the upper end portion, a central portion and the lower end portion of the boat 217 in a comparative example. According to the comparative example, an interval (spacing) between the mounting structures 217a of the boat 217 is constant in the upper end portion, the central portion and the lower end portion of the in the processing region. As shown in FIG. 4, the thickness of the film formed on the wafers 200 in the upper end portion and the lower end portion of the boat 217 is set to be larger than the thickness of the film formed on the wafers 200 in the central portion of the boat 217. In addition, when comparing the upper end portion and the lower end portion of the boat 217, the thickness of the film in the lower end portion tends to be larger. It is considered that such a phenomenon occurs because the exhaust pipe 231 shown in FIG. 1 is connected to a lower portion of the outer tube 203, and as a result, the reaction by-products in the lower end portion of the processing region are easily exhausted, and a concentration of the reaction by-products in the lower end portion of the processing region is low. With such a structure, a length (that is, a length in the arrangement direction of the wafers 200) “b” of a lower region (that is, the lower end portion) of the boat 217 is set to be longer than a length “a” of an upper region (that is, the upper end portion) of the boat 217. The lower region is close to the exhaust pipe 231, whereas the upper region is far from the exhaust pipe 231. Therefore, exhausting the gas on the wafer 200 arranged in the upper region is less easy than exhausting the gas on the wafer 200 arranged in a central region (that is, the central portion) of the boat 217. Thereby, an influence by a difference in exhaust conductance (or in easiness of exhausting the gas) is reduced. Therefore, while the thickness of the film in the lower region changes due to an influence by a difference in the amount of the reaction by-products generated and the influence by the casiness of exhausting the gas (that is, the exhaust conductance), it is considered that a change in the thickness of the film in the lower region is mainly due to the influence caused by the difference in the amount of the reaction by-products generated.

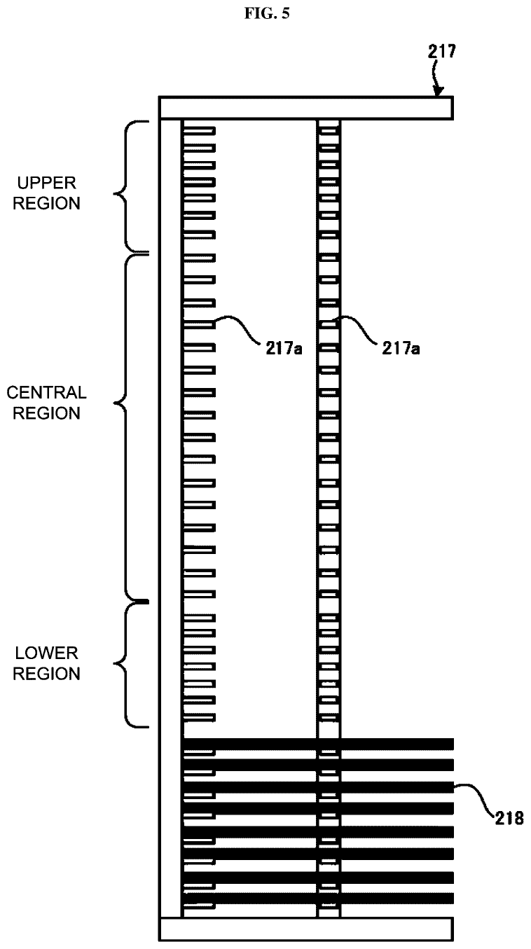

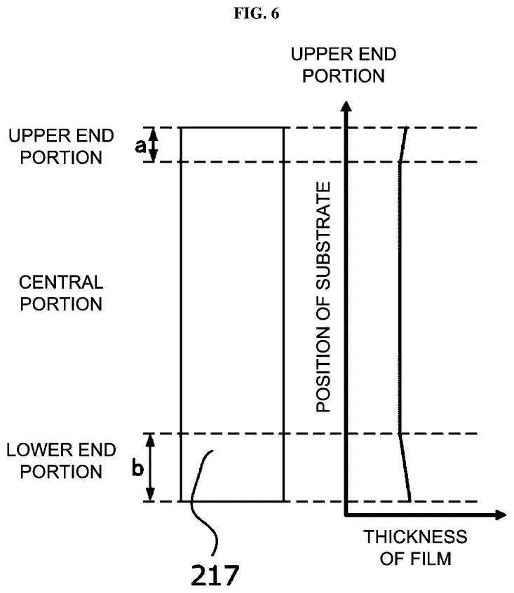

FIG. 5 is a diagram schematically illustrating a configuration of the boat 217 according to the present embodiments, and FIG. 6 is a diagram schematically illustrating a relationship (positional relationship) between the thickness of the film formed on the wafers 200 accommodated in the boat 217 and the positions in the upper end portion, the central portion and the lower end portion of the boat 217 in the present embodiments. According to the present embodiments, the interval (spacing) between adjacent wafers among the wafers 200 in the boat 217 corresponding to the upper end portion and the lower end portion of the processing region (that is, corresponding to the region where the amount of the reaction by-products is smaller than other regions of the processing region) is adjusted. For example, the interval between the wafers 200 in the boat 217 corresponding to the upper end portion and the lower end portion of the processing region is set to be narrower than the interval between the wafers 200 in the boat 217 corresponding to the central portion of the processing region. In other words, the interval between the mounting structures 217a of the boat 217 corresponding to the upper region and the lower region is set to be narrower than the interval between the mounting structures 217a of the boat 217 corresponding to the central region. By narrowing the interval between the wafers 200, it is possible to obtain one or more of the following effects. For example, the concentration of the reaction by-products generated in the upper end portion and the lower end portion of the processing region can be set to be closer to the concentration of the reaction by-products generated in the central portion of the processing region. By narrowing the interval (substrate spacing), it is possible to increase the number of the wafers 200 (or a density of the wafers 200). Thereby, it is possible to increase the amount of the reaction by-products generated in the vicinity of the surfaces of the wafers 200. In addition, by narrowing the substrate spacing, the gas cannot easily flow between the wafers 200, so that an amount of the process gas supplied to the wafers 200 arranged in the upper end portion and the lower end portion of the processing region is set to be smaller than the amount of the process gas supplied to the wafers 200 arranged in the central portion of the processing region. Thereby, the thickness of the film formed on the wafers 200 in the upper end portion and the lower end portion of the processing region is reduced. As a result, it is possible to prevent the thickness of the film formed on the wafers 200 in the upper end portion and the lower end portion of the processing region from being larger than the thickness of the film formed on the wafers 200 in the central portion of the processing region. Thereby, it is possible to improve a uniformity of the thickness of the film formed on the wafers 200 for each of the wafers (substrates) (that is, the uniformity of the substrate processing between the wafers 200), and it is also possible to uniformize characteristics of the film.

That is, in order to improve a non-uniformity of the thickness of the film for each of the wafers 200, as shown in FIG. 5, the substrate spacing in the central region on the central portion of the boat 217 is set to be a “first spacing”, the substrate spacing in the upper region on the upper end portion of the boat 217 is set to be a “second spacing”, and the substrate spacing in the lower region on the lower end portion of the boat 217 is set to be a “third spacing”. Each of the second spacing and the third spacing is set to be smaller than the first spacing. By narrowing the interval between the wafers 200, it is possible to reduce an inflow amount of the process gas flowing between the wafers 200, and it is also possible to reduce the thickness of the film formed on the wafers 200. As a result, the thickness of the film formed on the wafers 200 arranged in a region where the substrate spacing is narrow (that is, a region corresponding to the second spacing and a region corresponding to the third spacing) can be set to be closer to the thickness of the film formed on the wafers 200 arranged in a region corresponding to the first spacing. That is, it is possible to reduce the difference between the thickness of the film formed on the wafers 200 arranged in the upper end portion and the lower end portion of the boat 217 and the thickness of the film formed on the wafers 200 arranged in the central portion of the boat 217.

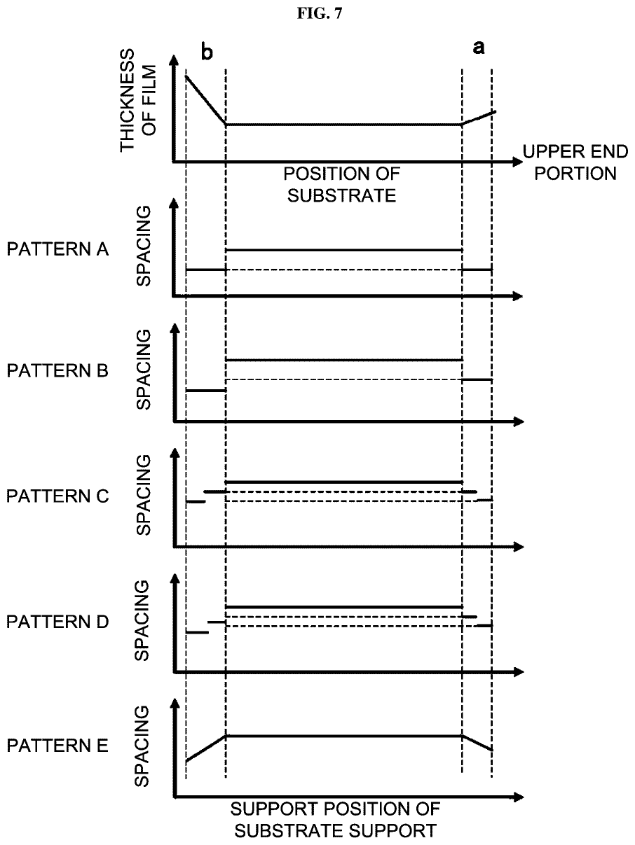

For example, the substrate spacing may be set to be the one illustrated as a pattern “A” shown in FIG. 7. In the pattern A, there is a relationship that the first spacing is greater than each of the second spacing and the third spacing, and the second spacing is equal to the third spacing. In addition, as shown in FIG. 4 mentioned above, the thickness of the film tends to be thicker at the lower end portion of the boat 217. Therefore, preferably, the third spacing may be set to be smaller than the second spacing. Thereby, it is possible to reduce the difference in the thickness of the film between the upper end portion and the lower end portion of the boat 217. Thus, for example, the substrate spacing may be set to be the one illustrated as a pattern “B” shown in FIG. 7. In the pattern B, there is a relationship that the first spacing is greater than the second spacing, and the second spacing is greater than the third spacing. In other words, since the thickness of the film tends to be thicker as it gets closer to the exhaust pipe 231, the substrate spacing in a portion closest to the exhaust pipe 231 is set to be narrower than the substrate spacing in another portion furthest from the exhaust pipe 231 in the processing region. In the substrate processing apparatus 10 shown in FIG. 1, the exhaust pipe 231 is provided on the lower end portion of the boat 217. Therefore, the third spacing is set to be small.

For example, when the first spacing is set to be “1”, the second spacing is set to be from 0.5 times to 0.9 times the first spacing, and the third spacing is set to be from 0.2 times to 0.9 times the first spacing. In addition, in the present specification, a notation of a numerical range such as “from 0.5 times to 0.9 times” means that a lower limit and an upper limit are included in the numerical range. Therefore, for example, a numerical range “from 0.5 times to 0.9 times” means a range equal to or higher than 0.5 times and equal to or less than 0.9 times. The same also applies to other numerical ranges described in the present specification. As described above, the length b of the lower region in the arrangement direction of the wafers 200 is set to be longer than the length a of the upper region in the arrangement direction of the wafers 200. For example, the upper region may refer to a region extending from an upper end of the boat 217 to a height lower than the upper end by 1/7 to 1/20 of a total length of the boat 217. For example, the lower region may refer to a region from a lower end of the boat 217 to a height higher than the lower end by 1/7 to 1/20 of the total length of the boat 217.

In addition, as shown in FIG. 4, the thickness of the film in the upper end portion of the boat 217 tends to increase toward the upper end. Further, in the lower end portion of the boat 217, the thickness of the film tends to increase toward the lower end. In order to correspond to such a gradual increase (continuous increase) in the thickness of the film depending on the position of the wafer 200, the substrate spacing in the upper end portion and the lower end portion of the boat 217 may be configured to differ in a stepwise manner. For example, the substrate spacing may be set to be the one illustrated as a pattern “C,” a pattern D or a pattern “E” shown in FIG. 7. In patterns C and D, two or more regions with different substrate spacings are provided in each of the upper end portion and the lower end portion. In the pattern C, the substrate spacing is the same between the upper end portion and the lower end portion. In the pattern D, the substrate spacing in the lower end portion is set to be narrower than that in the upper end portion. More preferably, as in the pattern E, the substrate spacing in the upper end portion and the lower end portion of the boat 217 may change continuously. In the present embodiments, when the substrate spacing changes continuously, it refers to a case where the substrate spacing differs for each pair of adjacent substrates (wafers). That is, the substrate spacing in the upper end portion and the lower end portion of the boat 217 may be set to be wider toward the central portion of the boat 217. In such a case, the substrate spacing in an uppermost end portion of the boat 217 may be set to be wider than the substrate spacing in a lowermost end portion of the boat 217. For example, the product substrates may be provided (placed) in at least one among the lower region and the upper region, and the dummy wafers may be provided (placed) in at least one among the lower region and the upper region. For example, the product substrates and the dummy wafers may be provided (placed) in at least one among the lower region and the upper region. In such a case, the substrate spacing in a region where the dummy wafers are placed is set to be narrower than the substrate spacing in another region where the product substrates are placed. Thereby, it is possible to improve the uniformity of the thickness of the film formed on the wafers 200 for each of the product substrates, and it is also possible to uniformize the characteristics of the film. For example, the dummy wafers may be provided (placed) in either the lower region or the upper region whose substrate spacing is set to be wider. In other words, the substrate spacing in the region where the dummy wafers are placed may be set to be wider than the substrate spacing in the region where the product substrates are placed. For example, since the lower region is closer to the exhaust pipe 231 than the upper region, a stagnation time of the process gas supplied into the process chamber 201 is short (also referred to as “a passage time of the process gas through the process chamber 201 is short”). With such a structure, by setting the substrate spacing in the region where the dummy wafers are placed not to be wider than the substrate spacing in the region where the product substrates are placed, it is possible to further shorten the passage time of the gas (process gas) through the process chamber 201. Thereby, it is possible to reduce the amount of the process gas adsorbed to the dummy wafers or the product wafers placed in the lower region, and it is also possible to reduce an increase in the thickness of the film.

In addition, in the patterns shown in FIG. 7, the substrate spacing in each of the upper region and the lower region is set to be narrower than the substrate spacing in the central region. However, the present embodiments are not limited thereto. For example, the substrate spacing may be set to be narrower in the region closer to the exhaust pipe 231, where the above-mentioned influence is most remarkable. In other words, the substrate spacing in the lower region is set to be narrower than the substrate spacing in the other regions. Specifically, it is preferable to configure the relationship such that the third spacing is greater than the first spacing, and the first spacing is equal to the second spacing.

### <Configuration of Controller>

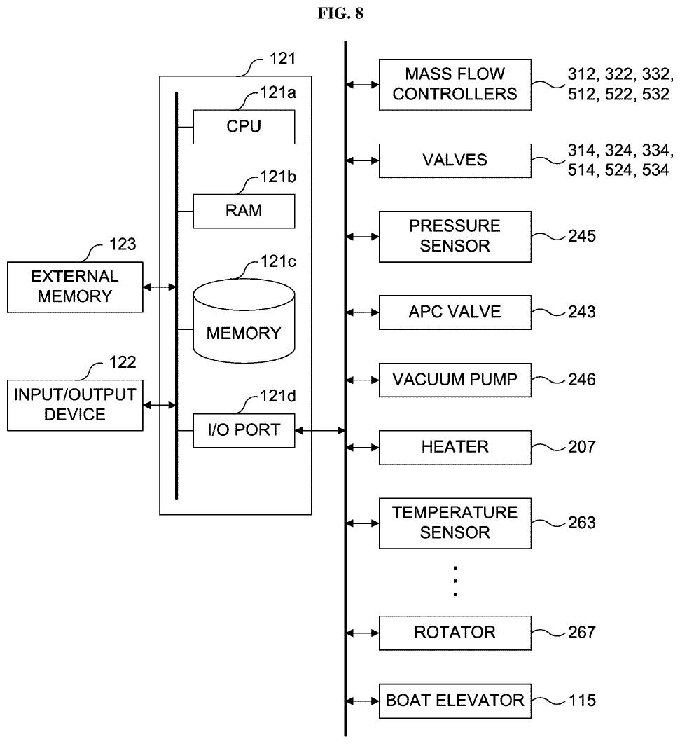

As shown in FIG. 8, a controller 121 serving as a control structure is constituted by a computer including a CPU (Central Processing Unit) 121a, a RAM (Random Access Memory) 121b, a memory 121c and an I/O port (input/output port) 121d. The RAM 121b, the memory 121c and the I/O port 121d may exchange data with the CPU 121a through an internal bus. For example, an input/output device 122 constituted by a component such as a touch panel is connected to the controller 121.

The memory 121c is configured by a component such as a flash memory and a hard disk drive (HDD). For example, a control program configured to control an operation of the substrate processing apparatus 10 or a process recipe containing information on procedures and conditions of the method of manufacturing the semiconductor device (that is, a substrate processing method) described later is readably stored in the memory 121c. The process recipe is obtained by combining steps (procedures) of the method of manufacturing the semiconductor device described later such that the controller 121 can execute the steps to acquire a predetermined result, and functions as a program. Hereafter, the process recipe and the control program may be collectively or individually referred to as a “program.” Thus, in the present specification, the term “program” may refer to the process recipe alone, may refer to the control program alone, or may refer to a combination of the process recipe and the control program. The RAM 121b functions as a memory area (work area) where a program or data read by the CPU 121a is temporarily stored.

The I/O port 121d is connected to the components of the process furnace 202 described above such as the MFCs 312, 322, 332, 512, 522 and 532, the valves 314, 324, 334, 514, 524 and 534, the pressure sensor 245, the APC valve 243, the vacuum pump 246, the heater 207, the temperature sensor 263, the rotator 267 and the boat elevator 115.

The CPU 121a is configured to read the control program from the memory 121c and execute the read control program. In addition, the CPU 121a is configured to read a recipe such as the process recipe from the memory 121c in accordance with an operation command inputted from the input/output device 122. In accordance with the contents of the read recipe, the CPU 121a may be configured to control various operations such as flow rate adjusting operations for various gases by the MFCs 312, 322, 332, 512, 522 and 532, opening and closing operations of the valves 314, 324, 334, 514, 524 and 534, an opening and closing operation of the APC valve 243, a pressure adjusting operation by the APC valve 243 based on the pressure sensor 245, a temperature adjusting operation by the heater 207 based on the temperature sensor 263, a start and stop of the vacuum pump 246, an operation of adjusting a rotation and a rotation speed of the boat 217 by the rotator 267, an elevating and lowering operation of the boat 217 by the boat elevator 115 and an operation of transferring and accommodating the wafer 200 into the boat 217.

The controller 121 may be embodied by installing the above-described program stored in an external memory 123 into the computer. For example, the external memory 123 may include a magnetic tape, a magnetic disk such as a flexible disk and a hard disk, an optical disk such as a CD and a DVD, a magneto-optical disk such as an MO and a semiconductor memory such as a USB memory and a memory card. The memory 121c or the external memory 123 may be embodied by a non-transitory computer readable recording medium storing a computer program. Hereafter, the memory 121c and the external memory 123 are collectively or individually referred to as a “recording medium”. Thus, in the present specification, the term “recording medium” may refer to the memory 121c alone, may refer to the external memory 123 alone, and may refer to both of the memory 121c and the external memory 123. Instead of the external memory 123, a communication structure such as the Internet and a dedicated line may be used for providing the program to the computer.

### (2) Substrate Processing

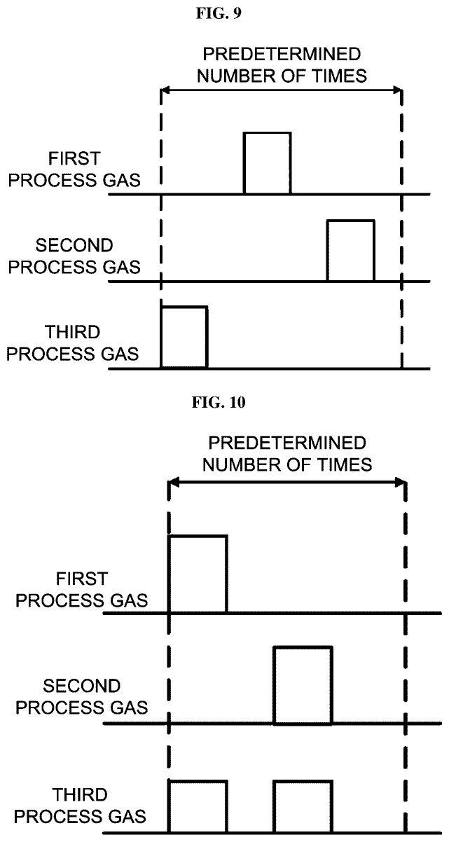

Hereinafter, as a part of a manufacturing process of the semiconductor device, an example of the substrate processing of forming the film on the wafer 200 will be described with reference to FIG. 9. The substrate processing is performed by using the process furnace 202 of the substrate processing apparatus 10 described above. In the following description, operations of the components constituting the substrate processing apparatus 10 are controlled by the controller 121.

In the substrate processing (that is, the manufacturing process of the semiconductor device) according to the present embodiments, when the adsorption inhibiting gas is used as the third process gas, it is possible to form the film on the wafer 200 by performing:
(a) supplying the third process gas to the wafer 200;
(b) supplying the first process gas to the wafer 200; and
(c) supplying the second process gas to the wafer 200,
wherein (b) and (c) are performed after (a).

In the present specification, the term “wafer” may refer to “a wafer itself,” or may refer to “a wafer and a stacked structure (aggregated structure) of a predetermined layer (or layers) or a film (or films) formed on a surface of the wafer.” In the present specification, the term “a surface of a wafer” may refer to “a surface of a wafer itself,” or may refer to “a surface of a predetermined layer (or a predetermined film) formed on a wafer.” Thus, in the present specification, “forming a predetermined layer (or a film) on a wafer” may refer to “forming a predetermined layer (or a film) directly on a surface of a wafer itself,” or may refer to “forming a predetermined layer (or a film) on a surface of another layer (or another film) formed on a wafer.” In the present specification, the terms “substrate” and “wafer” may be used as substantially the same meaning.

### <Wafer Charging Step and Boat Loading Step>

The wafers 200 are charged (transferred) into the boat 217 (wafer charging step). After the boat 217 is charged with the wafers 200, as shown in FIG. 1, the boat 217 charged with the wafers 200 is elevated by the boat elevator 115 and loaded (transferred) into the process chamber 201 to be accommodated therein (boat loading step). With the boat 217 loaded, the seal cap 219 seals a lower end opening of the outer tube 203 via the O-ring 220.

### <Pressure Adjusting Step and Temperature Adjusting Step>

The vacuum pump 246 vacuum-exhausts the inner atmosphere of the process chamber 201 such that the inner pressure of the process chamber 201 (that is, a pressure in a space in which the wafers 200 are accommodated) reaches and is maintained at a desired pressure (vacuum degree). Meanwhile, the inner pressure of the process chamber 201 is measured by the pressure sensor 245, and the APC valve 243 is feedback-controlled based on pressure information measured by the pressure sensor 245 (pressure adjusting step). The vacuum pump 246 continuously vacuum-exhausts the inner atmosphere of the process chamber 201 until at least a processing of the wafer 200 is completed. In addition, the heater 207 heats the process chamber 201 such that the inner temperature of the process chamber 201 reaches and is maintained at a desired temperature. Meanwhile, the amount of the electric current supplied to the heater 207 is feedback-controlled based on the temperature information detected by the temperature sensor 263 such that the desired temperature distribution of the inner temperature of the process chamber 201 is obtained (temperature adjusting step). The heater 207 continuously heats the process chamber 201 until at least the processing of the wafer 200 is completed.

### <Third Process Gas Supply: First Step>

The valve 334 is opened to supply the third process gas into the gas supply pipe 330. A flow rate of the third process gas is adjusted by MFC 332. Then, the third process gas whose flow rate is adjusted is supplied into the process chamber 201 through the gas supply holes 430a of the nozzle 430, and is exhausted through the exhaust pipe 231. In the present step, in parallel with a supply of the third process gas, the valve 534 may be opened to supply the inert gas into the gas supply pipe 530. Further, in order to prevent the third process gas from entering the nozzles 410 and 420, the valves 514 and 524 may be opened to supply the inert gas into the gas supply pipes 510 and 520.

In the present step, for example, a supply flow rate of the third process gas controlled by the MFC 332 can be set to a flow rate within a range from 0.1 slm to 5.0 slm.

In the present step, the third process gas is supplied to the wafer 200. As the third process gas, for example, the adsorption inhibiting gas may be used.

As the inert gas, for example, nitrogen (N₂) gas may be used. As the inert gas, for example, instead of or in addition to the N₂gas, a rare gas such as argon (Ar) gas, helium (He) gas, neon (Ne) gas and xenon (Xe) gas may be used. As the inert gas, for example, one or more of the gases exemplified above may be used.

### <Purge: Second Step>

After a predetermined time has elapsed from the supply of the third process gas, the valve 334 is closed to stop the supply of the third process gas. In the present step, with the APC valve 243 of the exhaust pipe 231 open, the vacuum pump 246 vacuum-exhausts the inner atmosphere of the process chamber 201 to remove the residual gas from above the wafer 200. Thereby, a substance such as the third process gas (which remains unreacted) and the reaction by-products remaining in the process chamber 201 can be removed from the process chamber 201. Further, in the present step, the valves 514, 524 and 534 are opened to supply the inert gas serving as a purge gas into the process chamber 201. The inert gas acts as the purge gas, which improves an efficiency of removing the substance such as the third process gas (which remains unreacted) and the reaction by-products remaining in the process chamber 201 out of the process chamber 201. For example, each supply flow rate of the inert gas controlled by each of the MFCs 512, 522 and 532 can be set to a flow rate within a range from 0.1 slm to 30.0 slm.

### <First Process Gas Supply: Third Step>

The valve 314 is opened to supply the first process gas into the gas supply pipe 310. A flow rate of the first process gas is adjusted by MFC 312. Then, the first process gas whose flow rate is adjusted is supplied into the process chamber 201 through the gas supply holes 410a of the nozzle 410, and is exhausted through the exhaust pipe 231. In the present step, in parallel with a supply of the first process gas, the valve 514 may be opened to supply the inert gas into the gas supply pipe 510. Further, in order to prevent the first process gas from entering the nozzles 420 and 430, the valves 524 and 534 may be opened to supply the inert gas into the gas supply pipes 520 and 530.

In the present step, for example, the APC valve 243 is appropriately adjusted (or controlled) such that the inner pressure of the process chamber 201 can be set to a pressure within a range from 1 Pa to 3,990 Pa. For example, a supply flow rate of the first process gas controlled by the MFC 312 can be set to a flow rate within a range from 0.01 slm to 7.0 slm. Hereinafter, for example, a temperature of the heater 207 can be set such that a temperature of the wafer 200 reaches and is maintained at a temperature within a range from 300° C. to 650° C.

In the present step, the first process gas is supplied to the wafers 200 in an entirety of the processing region. As the first process gas, for example, a gas containing halogen (for example, a gas containing a primary element (main element) constituting the film and chlorine (Cl) serving as the halogen) may be used. By supplying the first process gas, a molecule of the first process gas is adsorbed onto the wafer 200 (that is, on a base film on the surface of the wafer 200). Thereby, a layer containing the primary element (also referred to as a “primary element-containing layer”) is formed on the wafer 200.

### <Purge: Fourth Step>

After a predetermined time has elapsed from the supply of the first process gas, the valve 314 is closed to stop the supply of the first process gas. In the present step, with the APC valve 243 of the exhaust pipe 231 open, the vacuum pump 246 vacuum-exhausts the inner atmosphere of the process chamber 201 to remove the residual gas from above the wafer 200. Thereby, a substance such as the first process gas (which remains unreacted) and the reaction by-products remaining in the process chamber 201 can be removed from the process chamber 201. Further, in the present step, the valves 514, 524 and 534 are opened to supply the inert gas serving as the purge gas into the process chamber 201. The inert gas acts as the purge gas, which improves an efficiency of removing the substance such as the first process gas (which remains unreacted) and the reaction by-products remaining in the process chamber 201 out of the process chamber 201. For example, each supply flow rate of the inert gas controlled by each of the MFCs 512, 522 and 532 can be set to a flow rate within a range from 0.1 slm to 30.0 slm.

### <Second Process Gas Supply: Fifth Step>

The valve 324 is opened to supply the second process gas into the gas supply pipe 320. A flow rate of the second process gas is adjusted by MFC 322. Then, the second process gas whose flow rate is adjusted is supplied into the process chamber 201 through the gas supply holes 420a of the nozzle 420, and is exhausted through the exhaust pipe 231. Thereby, the second process gas is supplied to the wafer 200.

In the present step, for example, the APC valve 243 is appropriately adjusted (or controlled) such that the inner pressure of the process chamber 201 can be set to a pressure within a range from 1 Pa to 3,990 Pa. For example, a supply flow rate of the second process gas controlled by the MFC 322 can be set to a flow rate within a range from 0.1 slm to 150.0 slm.

In the present step, the second process gas is supplied to the wafers 200 in the entirety of the processing region. In the present embodiments, the second process gas serves as a reactive gas. A substitution reaction occurs between the reactive gas and at least a portion of the primary element-containing layer formed on the wafer 200. During the substitution reaction, the primary element contained in the primary element-containing layer and an atom contained in the reactive gas are bonded together. As a result, a layer containing the primary element and the element contained in the reactive gas can be formed on the wafer 200. In addition, during the substitution reaction, the reaction by-products are also generated.

### <Purge: Sixth Step>

After a predetermined time has elapsed from the supply of the second process gas, the valve 324 is closed to stop the supply of the second process gas. In the present step, with the APC valve 243 of the exhaust pipe 231 open, the vacuum pump 246 vacuum-exhausts the inner atmosphere of the process chamber 201 to remove the residual gas from above the wafer 200. Thereby, a substance such as the second process gas (which remains unreacted or which contributed to the formation of the film) and the reaction by-products remaining in the process chamber 201 can be removed from the process chamber 201. Further, in the present step, the valves 514, 524 and 534 are opened to supply the inert gas serving as the purge gas into the process chamber 201. The inert gas acts as the purge gas, which improves an efficiency of removing the substance such as the second process gas (which remains unreacted or which contributed to the formation of the film) and the reaction by-products remaining in the process chamber 201 out of the process chamber 201. For example, each supply flow rate of the inert gas controlled by each of the MFCs 512, 522 and 532 can be set to a flow rate within a range from 0.1 slm to 30.0 slm.

In other words, it is possible to remove the substance such as the second process gas (which remains unreacted or which contributed to the formation of the film) and the reaction by-products remaining in the process chamber 201 from the process chamber 201. As described above, The inert gas acts as the purge gas.

### <Performing Predetermined Number of Times>

By performing a cycle (in which the first step to the sixth step described above are sequentially performed in this order) a predetermined number of times (n times, n is an integer of 1 or more), the film of a predetermined thickness is formed on the wafer 200.

### <After-Purge Step and Returning to Atmospheric Pressure Step>

The inert gas is supplied into the process chamber 201 through each of the gas supply pipes 510, 520 and 530, and is exhausted through the exhaust pipe 231. The inert gas serves as the purge gas, and the inner atmosphere of the process chamber 201 is purged with the inert gas. Thus, the substance such as the residual gas in the process chamber 201 and the reaction by-products remaining in the process chamber 201 can be removed from the process chamber 201 (after-purge step). Thereafter, the inner atmosphere of the process chamber 201 is replaced with the inert gas (substitution by inert gas), and the inner pressure of the process chamber 201 is returned to a normal pressure (atmospheric pressure) (returning to atmospheric pressure step).

### <Boat Unloading Step and Wafer Discharging Step>

Thereafter, the seal cap 219 is lowered by the boat elevator 115 and the lower end of the outer tube 203 is opened. The boat 217 with the wafers (which are processed) 200 charged therein is unloaded out of the outer tube 203 through the lower end of the outer tube 203 (boat unloading step). Then, the wafers (which are processed) 200 are discharged (transferred) out of the boat 217 (wafer discharging step).

In other words, by using the substrate processing apparatus 10 as described above to perform a batch processing in which the plurality of wafers 200 are processed simultaneously, it is possible to improve a processing uniformity (that is, the uniformity of the substrate processing) between the wafers 200 processed in the batch processing.

### (3) Effects According to Present Embodiments

According to the present embodiments, it is possible to obtain one or more of the following effects.
(a) It is possible to improve the processing uniformity between the substrates (that is, the wafers 200).
(b) It is possible to improve a processing uniformity of the substrate (that is, the wafer 200) within the surface of the substrate (that is, the wafer 200).
(c) It is possible to uniformize the characteristics (electrical characteristics) of the film formed on the substrate (that is, the wafer 200).

The technique of the present disclosure is described in detail by way of the embodiments mentioned above. However, the technique of the present disclosure is not limited thereto. The technique of the present disclosure may be modified in various ways without departing from the scope thereof.

For example, in the substrate processing mentioned above, the third process gas may be supplied as shown in FIG. 10. FIG. 10 is a diagram schematically illustrating an example in which the third process gas is used as a dilution gas, and the third process gas is supplied when the first process gas is supplied and when the second process gas is supplied. Even in the present modified example, it is possible to obtain substantially the same effects as in the embodiments mentioned above. In addition, according to the present modified example, it is possible to further shorten a process time.

For example, the embodiments mentioned above are described by way of an example in which the purge (that is, the second step, the fourth step and the sixth step) is performed between the first process gas supply (that is, the third step), the second process gas supply (that is, the fifth step) and the third process gas supply (that is, the first step). However, the technique of the present disclosure is not limited thereto. For example, the purge may not be performed between the first process gas supply, the second process gas supply and the third process gas supply. Even in the present modified example, it is possible to obtain substantially the same effects as in the embodiments mentioned above. In addition, according to the present modified example, it is possible to further shorten the process time.

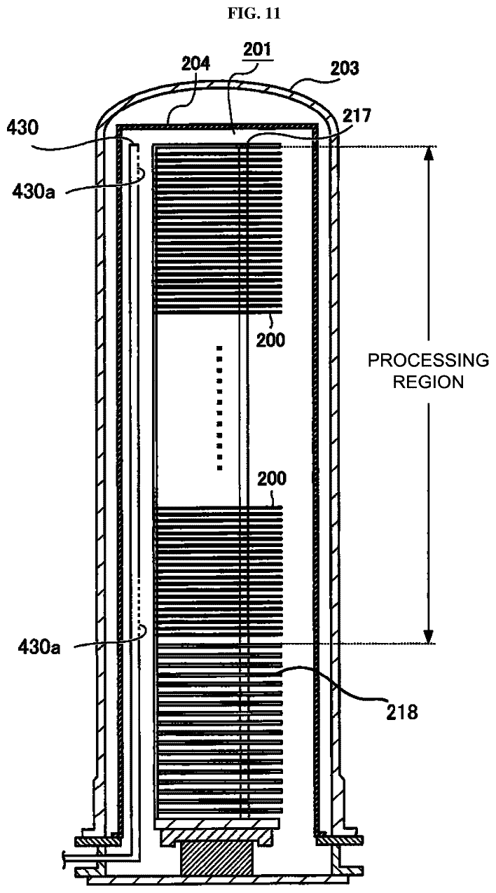

For example, the embodiments mentioned above are described by way of an example in which the nozzle 430 provided with the gas supply holes 430a is used for the entirety of the processing region from the upper end portion to the lower end portion. However, the technique of the present disclosure is not limited thereto. For example, as shown in FIG. 11, the nozzle 430 provided with the gas supply holes 430a only at positions facing the upper end portion and the lower end portion of the processing region may be used. That is, the gas supply holes 430a are not provided at positions facing the central portion of the processing region. That is, the nozzle 430 according to the present modified example is configured to supply the third process gas only to the upper region and the lower region rather than the central region. As the third process gas, for example, a gas such as the inert gas, a reaction inhibiting gas and the adsorption inhibiting gas may be used. For example, by supplying the inert gas as the third process gas, it is possible to dilute the first process gas and the second process gas supplied to the upper end portion and the lower end portion of the processing region. Thus, by diluting the first process gas and the second process gas, it is possible to adjust an amount of the first process gas and an amount of the second process gas supplied to the wafer 200. For example, by increasing a supply amount of the inert gas to increase a dilution amount of the first process gas and the second process gas, it is possible to reduce an amount of the reaction in the upper end portion and the lower end portion of the processing region. In addition, the thickness of the film formed on the wafers 200 arranged in the upper end portion and the lower end portion of the processing region can be set to be closer to the thickness of the film formed on the wafers 200 arranged in the central portion of the processing region.

When the adsorption inhibiting gas (reaction inhibiting gas) is used as the third process gas, it is possible to supply the adsorption inhibiting gas to the wafers 200 arranged in the upper end portion and the lower end portion of the processing region. It is possible to suppress an adsorption of at least one among the first process gas and the second process gas onto the wafer 200 when a molecule of the adsorption inhibiting gas is adsorbed to the wafer 200. In other words, it is possible to limit the amount of the reaction between the molecules of the first process gas and the second process gas on the wafer 200.

In addition, in the nozzle 430 shown in FIG. 11, the gas supply holes 430a are provided only at the positions facing the upper end portion and the lower end portion of the processing region without being provided at the positions facing the central portion of the processing region. However, the technique of the present disclosure is not limited thereto. For example, the gas supply holes 430a may be provided over entire positions of the nozzle 430 facing the processing region, and a size of each of the gas supply holes 430a arranged in the upper end portion and the lower end portion may be set to be larger than the size of each of the gas supply holes 430a arranged in the central portion of the processing region. In addition, the thickness of the film formed on the wafer 200 tends to be thicker at the lower end portion as compared with the upper end portion of the processing region. Thus, as shown in FIG. 11, a length of a region where the gas supply holes 430a are located may be greater in the lower end portion than in the upper end portion of the processing region. With such a configuration, the thickness of the film formed on the wafers 200 arranged in the lower end portion of the processing region can be set to be closer to the thickness of the film formed on the wafers 200 arranged in the other portions (regions) of the processing region. In the example shown in FIG. 11, the molecule of the adsorption inhibiting gas and some material contained in the adsorption inhibiting gas are adsorbed onto the wafers 200 (that is, onto a base film on the surfaces of the wafers 200) arranged in the upper end portion and the lower end portion of the processing region.

For example, the embodiments mentioned above may be preferably applied when a film containing at least one among titanium (Ti), aluminum (Al), hafnium (Hf), zirconium (Zr), molybdenum (Mo), tungsten (W), ruthenium (Ru), silicon (Si) and the like is formed on the wafer 200. In addition, as the film containing at least one among the elements exemplified above, a film such as a metal film, an oxide film, a nitride film and a carbide film may be formed.

For example, in the embodiments mentioned above, a gas containing a metal element and the halogen (for example, TiCl gas) may be used as the first process gas. However, the technique of the present disclosure is not limited thereto. For example, the technique of the present disclosure may be preferably applied when a gas such as aluminum chloride (AlCl₃) gas, hafnium chloride (HfCl₄) gas, zirconium chloride (ZrCl₄) gas, molybdenum pentachloride (MoCl₅) gas, molybdenum dioxide dichloride (MoO₂Cl₂) gas, molybdenum oxide tetrachloride (MoOCl₄) gas, tungsten hexafluoride (WF₆) gas, tungsten hexachloride (WCl₆) gas and a gas containing ruthenium (Ru) and the halogen is used as the first process gas. In addition, the embodiments mentioned above may be preferably applied when a gas containing a Group 14 element (such as silicon (Si) and germanium (Ge)) and the halogen is used as the first process gas. As the gas containing the Group 14 element, a gas such as hexachlorodisilane (Si₂Cl₆, abbreviated as HCDS) gas, dichlorosilane (SiH₂Cl₂, abbreviated as DCS) gas and germanium chloride (Ge₂Cl₆) gas may be used. When the gas containing the halogen (in particular, the gas containing chlorine (Cl)) is used as the first process gas, the reaction by-products mentioned above are generated, and the same phenomenon may occur.

For example, in the embodiments mentioned above, a gas containing nitrogen (N) and hydrogen (H) and serving as a reducing gas and the reactive gas (for example, NH₃ gas) may be used as the second process gas. However, the technique of the present disclosure is not limited thereto. For example, the technique of the present disclosure may be preferably applied when a gas containing at least one selected from the group of a gaseous mixture of N₂ and H₂, diazene (N₂H₂), triazene (N₃H₃), hydrazine (N₂H₄) and other gases containing an amine group is used as the second process gas. For example, when HCl gas is used as the adsorption inhibiting gas, the HCl gas reacts with the NH₃ gas to generate NH₄Cl. Therefore, it is preferable to use the NH₃ gas as the second process gas.

For example, as described above, the gas containing nitrogen and hydrogen is used as the second process gas. However, the technique of the present disclosure is not limited thereto. For example, a reducing gas free of nitrogen (that is, the reducing gas without containing nitrogen) may be used as the second process gas. For example, the technique of the present disclosure may be preferably applied when a gas containing at least one selected from the group of the H₂ gas, deuterium (D) gas, disilane (Si₂H₆) gas, trisilane (Si₃H₈) gas, monogermane (GeH₄) gas, digermane (Ge₂H₆) gas, trigermane (Ge₃H₆) gas, monoborane (BH₃) gas, diborane (B₂H₆) gas and phosphine (PH₃) gas is used as the second process gas. By using the reducing gas free of nitrogen, it is possible to form a film other than a nitride film.

For example, in the embodiments mentioned above, a gas containing halogen such as the HCl gas is used as the adsorption inhibiting gas. However, the technique of the present disclosure is not limited thereto. For example, the technique of the present disclosure may be preferably applied when a gas containing the same type of halogen as the halogen contained in the first process gas is used as the adsorption inhibiting gas. For example, a gas such as NH₄Cl gas, Cl₂ gas, BCl₃ gas, HF gas, and fluorine (F₂) gas may be used as the adsorption inhibiting gas. In addition, as the adsorption inhibiting gas, it is preferable to use a gas containing the same constituents as the reaction by-products generated by the reaction between the first process gas and the second process gas. Specifically, a gas containing the same type of halogen as the halogen contained in the first process gas may be used as the adsorption inhibiting gas. As the gas containing the same type of halogen as the halogen contained in the first process gas, hydrogen chloride (HCl) gas or ammonium chloride (NH₄Cl) gas, which is the reaction by-products generated by the reaction between the first process gas (such as titanium tetrachloride (TiCl₄) gas) and the second process gas (such as ammonia (NH₃) gas), may be used. In addition, as the adsorption inhibiting gas, a gas containing chlorine (Cl) may be used. As the gas containing chlorine, for example, a gas such as the HCl gas, chlorine (Cl₂) gas, boron trichloride (BCl₃) gas may be used. As the third process gas, for example, one or more of the substances exemplified above may be used.

For example, as the adsorption inhibiting gas, by using the gas containing the same type of halogen as the halogen contained in the first process gas, preferably by using the gas containing the same constituents as the reaction by-products generated by the reaction between the first process gas and the second process gas, it is possible to prevent (or suppress) the adsorption inhibiting gas from remaining in the film.

In other words, although the adsorption inhibiting gas is unlikely to remain in the film, depending on the conditions and the type of the gas, the adsorption inhibiting gas may remain in the film and may affect the electrical characteristics and other characteristics of the film. When the gas containing the same constituents as the reaction by-products generated by the reaction between the first process gas and the second process gas is used as the adsorption inhibiting gas, it is possible to reduce a possibility that the adsorption inhibiting gas affects other films constituting the semiconductor device. For example, in a case of forming a titanium nitride (TiN) film, when hydrogen fluoride (HF) gas is supplied as the adsorption inhibiting gas, fluorine (F) may remain. Thereby, a function of the TiN film as a fluorine barrier may be reduced. In addition, when the base film of the TiN film is an aluminum oxide (AlO) film, fluorine may diffuse into the AlO film. Thereby, insulating characteristics of the AlO film may be reduced. As described above, when the gas containing the same constituents as the reaction by-products generated by the reaction between the first process gas and the second process gas is used as the adsorption inhibiting gas, such problems are unlikely to occur.

For example, in the embodiments mentioned above, the film containing the metal clement and nitrogen may be formed on the wafer 200. However, the technique of the present disclosure is not limited thereto. For example, the technique of the present disclosure may be preferably applied when a film such as a metal film, a film mainly constituted by the Group 14 element, an oxide film, an oxynitride film and a carbide film is formed by appropriately selecting each gas.

For example, the embodiments mentioned above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of processing one or several substrates at a time is used to form the film. A processing region of the single wafer type substrate processing apparatus may be provided between the wafer and a gas supplier (which is a gas supply structure or a gas supply system) such as a shower head of the single wafer type substrate processing apparatus. By supplying the adsorption inhibiting gas to a portion of the processing region of the single wafer type substrate processing apparatus, it is possible to improve the processing uniformity of the wafer 200 within the surface of the wafer 200.

For example, the embodiments mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film.

The process procedures and the process conditions of each process using the substrate processing apparatuses exemplified above may be substantially the same as those of the embodiments or modified examples mentioned above. Even in such a case, it is possible to obtain substantially the same effects as in the embodiments or the modified examples mentioned above.

It is preferable that the process recipe (that is, a program defining parameters such as the process procedures and the process conditions of the substrate processing) used to form various films mentioned above is prepared individually in accordance with the contents of the substrate processing such as a type of the film to be formed, a composition ratio of the film, a quality of the film, a thickness of the film, the process procedures and the process conditions. That is, a plurality of process recipes are prepared. Then, when starting the substrate processing, an appropriate process recipe is preferably selected among the process recipes in accordance with the contents of the substrate processing. Specifically, it is preferable that the process recipes are stored (installed) in the memory 121c of the substrate processing apparatus 10 in advance via an electric communication line or the recording medium (for example, the external memory 123) storing the process recipes prepared individually in accordance with the contents of the substrate processing. Then, when starting the substrate processing, the CPU 121a preferably selects the appropriate process recipe among the process recipes stored in the memory 121c of the substrate processing apparatus 10 in accordance with the contents of the substrate processing. With such a configuration, various films of different types, different composition ratios, different qualities and different thicknesses can be universally formed in a reliably reproducible manner by using a single substrate processing apparatus. In addition, since a burden on an operating personnel such as inputting the process procedures and the process conditions can be reduced, various processes can be performed quickly while avoiding an error in operating the substrate processing apparatus.

Further, the technique of the present disclosure may be implemented by changing an existing process recipe stored in the substrate processing apparatus to a new process recipe. When changing the existing process recipe to the new process recipe, the new process recipe may be installed in the substrate processing apparatus via the electric communication line or the recording medium storing the process recipes. Alternatively, the existing process recipe already stored in the substrate processing apparatus may be directly changed to the new process recipe according to the technique of the present disclosure by operating the input/output device of the substrate processing apparatus.

Further, for example, the technique of the present disclosure may be used in a structure such as a word line of a DRAM and a 3D NAND flash memory of a three-dimensional structure.

The technique of the present disclosure may be applied even when the embodiments and the modified examples mentioned above are appropriately combined. For example, the process procedures and the process conditions of each process of such a combination may be substantially the same as those of the embodiments or the modified examples mentioned above.

As described above, according to some embodiments of the present disclosure, it is possible to improve the uniformity of the substrate processing between the substrates.

What is claimed is:

1. A substrate processing apparatus comprising:
a substrate support provided with a processing region in which a plurality of substrates are placed, and comprising a plurality of mounting structures on which the plurality of substrates are placed, respectively, such that a substrate spacing between adjacent substrates in an upper region of the processing region and a substrate spacing between adjacent substrates in a lower region of the processing region are set to be narrower than a substrate spacing between adjacent substrates in a central region of the processing region;
a process vessel configured to accommodate the substrate support;
a gas supplier configured to supply a process gas into the process vessel; and
an exhauster configured to exhaust an inner atmosphere of the process vessel.

2. The substrate processing apparatus of claim 1, wherein the substrate spacing between adjacent substrates in the lower region is set to be narrower than the substrate spacing between adjacent substrates in the upper region.

3. The substrate processing apparatus of claim 2, wherein at least one of the lower region or the upper region comprises two or more regions with different substrate spacings.

4. The substrate processing apparatus of claim 2, wherein at least one of the lower region or the upper region is configured such that the substrate spacing thereof becomes wider toward the central region.

5. The substrate processing apparatus of claim 2, wherein a length of the lower region along an arrangement direction of the plurality of substrates is set to be longer than a length of the upper region along the arrangement direction of the plurality of substrates.

6. The substrate processing apparatus of claim 1, wherein the lower region is located close to the exhauster.

7. The substrate processing apparatus of claim 1, wherein at least one of the lower region or the upper region comprises two or more regions with different substrate spacings.

8. The substrate processing apparatus of claim 1, wherein at least one of the lower region or the upper region comprises a region whose substrate spacing changes continuously toward the central region.

9. The substrate processing apparatus of claim 1, wherein at least one of the lower region or the upper region is configured such that the substrate spacing thereof becomes wider toward the central region.

10. The substrate processing apparatus of claim 1, wherein a length of the lower region along an arrangement direction of the plurality of substrates is set to be longer than a length of the upper region along the arrangement direction of the plurality of substrates.

11. The substrate processing apparatus of claim 1, wherein the upper region extends from an upper end of the substrate support to a height lower than the upper end by 1/7 to 1/20 of a total length of the substrate support.

12. The substrate processing apparatus of claim 1, wherein the lower region extends from a lower end of the substrate support to a height higher than the lower end by 1/7 to 1/20 of a total length of the substrate support.

13. The substrate processing apparatus of claim 1, wherein a dummy substrate is placed at a portion of at least one of the lower region or the upper region, and
wherein a product substrate is placed at a portion of at least one of the lower region or the upper region.

14. The substrate processing apparatus of claim 1, wherein a substrate spacing in a region where a dummy substrate is placed within at least one of the lower region or the upper region is set to be narrower than a substrate spacing in a region where a product substrate is placed.

15. The substrate processing apparatus of claim 1, wherein a substrate spacing in a region where a dummy substrate is placed within at least one of the lower region or the upper region is set to be wider than a substrate spacing in a region where a product substrate is placed.

16. The substrate processing apparatus of claim 1, wherein the gas supplier comprises:
a first nozzle through which a first process gas is supplied;
a second nozzle through which a second process gas is supplied; and
a third nozzle through which a third process gas is supplied,
wherein the first nozzle is configured to supply the first process gas to an entirety of the processing region, the second nozzle is configured to supply the second process gas to the entirety of the processing region, and the third nozzle is configured to supply the third process gas to the lower region and the upper region.

17. A substrate support configured to be loaded into a process vessel of a substrate processing apparatus and provided with a processing region in which a plurality of substrates are placed, the substrate support comprising:
a plurality of mounting structures on which the plurality of substrates are placed, respectively, such that a substrate spacing between adjacent substrates in an upper region of the processing region and a substrate spacing between adjacent substrates in a lower region of the processing region are set to be narrower than a substrate spacing between adjacent substrates in a central region of the processing region.

18. A substrate processing method using a substrate processing apparatus comprising: a substrate support provided with a processing region in which a plurality of substrates are placed, and comprising a plurality of mounting structures on which the plurality of substrates are placed, respectively, such that a substrate spacing between adjacent substrates in an upper region of the processing region and a substrate spacing between adjacent substrates in a lower region of the processing region are set to be narrower than a substrate spacing between adjacent substrates in a central region of the processing region; a process vessel configured to accommodate the substrate support; a gas supplier configured to supply a process gas into the process vessel; and an exhauster configured to exhaust an inner atmosphere of the process vessel, the substrate processing method comprising:
(a) loading the substrate support in which the plurality of substrates are placed into the process vessel;
(b) supplying the process gas to the plurality of substrates; and
(c) exhausting the inner atmosphere of the process vessel.

19. A method of manufacturing a semiconductor device, comprising:
the substrate processing method of claim 18.

20. A non-transitory computer-readable recording medium storing a program that causes a substrate processing apparatus, by a computer, to perform a process comprising the substrate processing method of claim 18.
